(19) United States
(12) Patent Application Publication
(10) Pub. No.: US 2008/0050871 A1
(43) Pub. Date: Feb. 28, 2008

(54) Methods for removing material from one layer of a semiconductor device structure while protecting another material layer and corresponding semiconductor device structures

(76) Inventor: Richard L. Stocks, Boise, ID (US)

Correspondence Address: TRASK BRITT, P.C./ MICRON TECHNOLOGY, P.O. BOX 2550, SALT LAKE CITY, UT, 84110, US

(21) Appl. No.: 11/510,202

(22) Filed: Aug. 25, 2006

(51) Int. Cl. H01L 21/8244

(52) U.S. Cl. 438/238

(57) ABSTRACT

Methods for removing material from one layer of a semiconductor device structure, such as an etch stop layer beneath a capacitor container, without substantially removing material from an overlying layer that includes the same material, such as a protective or reinforcing lattice over the capacitor container, include employing process parameters in which material may be removed from features, as desired, while a sufficient amount of polymer is formed and deposited on features from which material removal is not desired. Methods for designing suitable processes are also disclosed, as are semiconductor device structures that are formed using such processes.

### BACKGROUND OF THE INVENTION

1. Field of the Invention

Embodiments of the invention relate generally to the fabrication of semiconductor devices. More particularly, embodiments of the invention relates to methods of etching one layer while protecting another. More specifically, embodiments of the invention relates to methods of protecting a feature, such as a high surface area container for a capacitor, while removing material beneath the feature, such as an etch stop layer to facilitate communication with a contact or active-device region below a fabrication level, or elevation, of a capacitor.

2. Background of Related Art

The fabrication of semiconductor devices, such as integrated circuits and flat panel displays, involves multiple deposition and/or etching processes. During a deposition process, materials are deposited onto a substrate surface. Etching may be employed to define features from material films on the substrate surface. Etching may be accomplished by a number of different technologies. Etching is a challenge in the fabrication of modern high density semiconductor devices as, to achieve greater circuit density, modern semiconductor devices are scaled with increasingly narrow design constraints. One particularly noteworthy example of this trend is with computer memory.

Dynamic random access memories (DRAMs) are a widely used form of memory integrated circuits. DRAMs are comprised of memory cell arrays and peripheral circuitry required for cell access and external input and output. Each memory cell array is formed of a plurality of memory cells for storing bits of data. Typical memory cells include a capacitor for storing electric charges and a transistor for controlling charge and discharge of the capacitor. In view of the ever-decreasing feature sizes and ever-increasing densities of semiconductor devices, the complexity of capacitors has increased while the sizes of the features thereof have decreased and, consequently, become more delicate. For example, container capacitors may be shaped as upstanding tubes (cylinders) having oval or circular cross-sections. The electrode of a container capacitor includes a conductive layer lining the inner wall and bottom of the upstanding tube. The electrode communicates with the drain of an access transistor either directly or through an intermediately positioned contact plug. A dielectric layer is formed over the electrode and is sandwiched between that electrode and another electrode on the opposite surface thereof.

Container capacitors are generally high aspect ratio structures; that is, the container height is significantly greater than its width or diameter, resulting in a tall, narrow structure. During fabrication, a container substrate is formed to provide a support for the remainder of the capacitor. The depths of the container substrate may be controlled by an etch stop layer beneath the insulator layer from which the container substrate is fabricated. The narrow walls of the container substrate are very delicate and will be subject to further processing. The narrow walls may collapse, break, or otherwise incur damage during further processing. Therefore, a protective layer, such as relatively thick film of silicon nitride, may be deposited on the container substrate to provide structural support thereto during subsequent processing.

Prior to forming the electrode of a container capacitor, it is necessary to etch through, or “punch through,” the etch stop layer to expose the drain of the transistor or a contact plug that communicates with the drain. The etch stop layer may be formed from silicon nitride. When conventional punch through processes are employed, the protective layer on top of the walls of the container may be removed while the exposed areas of the etch stop layer are removed. This is particularly true where the protective layer and the etch stop include the same material or are etchable by the same etchants.

In order to continue protecting the container substrate during punch through, the protective layer may be thicker than its desired final thickness. The difference between the initial thickness of the protective layer and its final thickness may be about or at least the thickness of the etch stop layer (e.g., about 300 Å to about 400 Å). This results in a number of process inefficiencies, such as wasted protective layer material and increased processing time for the added thickness of the protective layer and later removal of the extra material and the accompanying consumption of valuable process chamber occupancy time. Additionally, the increased thickness of the protective layer results in a higher aspect ratio of the container substrate, which may increase the time required to effect punch through or otherwise decrease the effectiveness of the punch through process.

Processes in which the rate at which protective layers are removed from container substrates are reduced would be desirable, as would semiconductor device structures including container substrates with protective layers of reduced thicknesses thereover.

### BRIEF DESCRIPTION OF THE SEVERAL VIEWS OF THE DRAWINGS

A more particular description of embodiments of the invention briefly described above will be rendered by reference to specific embodiments thereof which are illustrated in the appended drawings. Understanding that these drawings depict only typical embodiments of the invention and are not therefore to be considered limiting of its scope, embodiments of the invention will be described and explained with additional specificity and detail through the use of the accompanying drawings in which:

FIG. 1 depicts a reactor chamber in which processes incorporating teachings of embodiments of the invention may be effected;

FIGS. 2A and 2B depict a semiconductor device structure with a semiconductor device feature that comprises a container capacitor, which may be fabricated by processes incorporating teachings of embodiments of the invention;

FIGS. 3A and 3B depict a result of experimentation with one version of a process that incorporates teachings of embodiments of the invention;

FIGS. 4, 5A, and 6A depict possible results of punch etches through an etch stop layer beneath a semiconductor device feature;

FIGS. 5B and 6B depict an embodiment of polymer deposition on an upper surface of a protective layer formed atop a semiconductor device feature during the punch through process;

FIG. 7 is a graph that charts etch depth versus time in one embodiment of the invention;

FIGS. 8A and 8B depict results of increased etch time according to one embodiment of the invention; and

FIGS. 9A and 9B illustrate the results of a process that incorporates teachings of embodiments of the invention.

### DETAILED DESCRIPTION OF THE INVENTION

In one aspect, embodiments of the invention include methods of removing (e.g., by dry etching) material exposed through a semiconductor device feature while reducing a removal rate of a protective layer that overlies at least a portion of the semiconductor device feature and that may be removed by the etchant or etchants (e.g., is formed from the same material as the material being removed). Such methods include forming a polymer primarily as material is being removed (e.g., during etching) and depositing the polymer primarily on the protective layer without substantially depositing the polymer on the surface of the material being removed. In addition, such methods may include continually removing the material until a desired depth is reached.

In another aspect, embodiments of the invention include methods of fabricating a semiconductor device structure with which the material removal aspect of embodiments of the invention may be effective. Such methods include forming a protective layer (e.g., a protective lattice) over at least one feature (e.g., a container substrate) of a semiconductor device structure. The semiconductor device feature is, in turn, located over an etch stop layer. The semiconductor device features, particularly opening therein, have height-aspect ratios that are sufficiently large that polymers are deposited primarily on the protective lattice, with substantially no polymer being deposited in the openings.

The deposition of polymer on the protective layer and the resultant effects of such deposition (i.e., removal of the protective layer at a slower rate) facilitates the use of thinner protective layers, which may be incorporated into semiconductor device design, yet another aspect of embodiments of the invention.

In a further aspect, embodiments of the invention include semiconductor device structures, including intermediate structures, with relatively thin protective layers and protective layers that are at least partially coated with polymer while there is substantially no polymer in openings of the semiconductor device features on which the protective layers are formed.

The term “semiconductor substrate,” as used herein, encompasses semiconductor dice, semiconductor wafers, partial wafers, and other bulk semiconductor substrates as well as devices and groups of devices singulated therefrom. As used herein, the term “semiconductor device structure” includes wafers and other bulk semiconductor substrates, partial wafers, groups of dice, and singulated dice. Such semiconductor device structures comprise both completed, packaged and unpackaged, integrated circuits, as well as in-process semiconductor device structures.

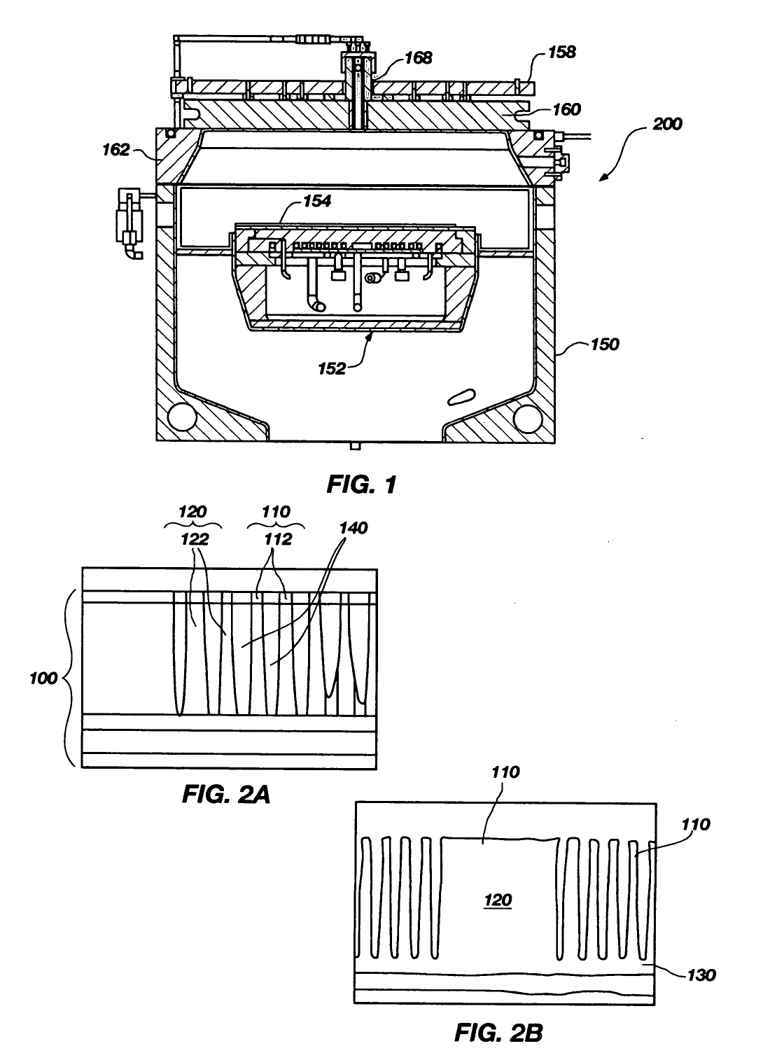

Processes that incorporate teachings of embodiments of the invention are suitable for etching materials exposed by large height-aspect ratio apertures or features. FIG. 1 illustrates one example of a reactor with which processes incorporating teachings of embodiments of the invention may be used. Any dry etch reactor, including plasma etch reactors or reactive ion etch reactors (RIE), may be used. The LAM 2300 DFC from LAM Research Corp. of Fremont, Calif., and the TEL DRM from Tokyo Electron Ltd. of Tokyo, Japan, are just two examples of dry etch reactors that may be used. Dry etch reactors include plasma etch reactors and reactive ion etch reactors (RIE). Plasma etch reactors may be generically viewed as top- and bottom-powered and operating at relatively high pressure. RIE reactors may be generically viewed as bottom-powered and operating at relatively low pressures.

FIG. 1 depicts an inductively-coupled reactor that may be used in either plasma etch mode or RIE mode. The reactor 200 comprises a reactor chamber 150. Inside chamber 150 is substrate support 152 including an electrostatic chuck 154, which provides a clamping force to a substrate (not shown) mounted thereon. The substrate support 152 may also be used to apply radio-frequency (RF) bias power to the substrate. Reactant gases may be introduced into the chamber 150 of reactor 200 via a gas injector 168 located on the top of chamber 150. As shown, an inductive coil 158 may be powered by a suitable RF source (not shown) to provide a plasma. The inductive coil 158 couples RF energy through dielectric window 160 into the interior of chamber 150. The annular member 162 spaces dielectric window 160 from the top of chamber 150 and is referred to as a “gas distribution plate.” The reactor 200 may also include suitable vacuum pumping apparatus (not shown) for maintaining the interior of the chamber at a desired pressure.

As is known in the art, dry etch reactors remove materials by causing positively charged ions to bombard the surface of the wafer (physical etching) and by reacting reactive species with a surface (chemical etching). Ions, reactive species, free radicals, and neutral compounds all may etch a surface. The phrase “ions and reactive species,” as used herein, encompasses any of the components of plasma that may affect etching. Complete separation of the physical and chemical etching mechanisms is difficult. The role of each varies depending upon process parameters. Ions may be produced within a plasma discharge over the wafer and accelerated towards the wafer by a negatively charged cathode (e.g., substrate support 152). The plasma discharge within a plasma etch reactor may be created by applying RF power to both the cathode and an anode (e.g., inductive coil 158) of the reactor 200, while the plasma discharge within an RIE reactor may be created by applying RF power to the cathode alone. In either type of reactor, the etch process may be highly anisotropic due to the substantially perpendicular acceleration of the positive ions towards the plane of the wafer. However, the reactors may be operated to allow isotropic etching, such as by reactive species. The anode (top power) may be inductively-coupled, capacitively-coupled, microwave, or any other top power source known in the art.

FIGS. 2A and 2B illustrate a semiconductor device structure 100 with a protective layer 110 formed above a semiconductor device feature, which, in the depicted example, is a container substrate that, for the sake of simplicity, may also be referred to herein as a “container” 140. Container 140 has been formed, as known in the art, by removing material from an intermediate layer 120 as far down as an etch stop layer 130. Such removal may be effected through a hard mask, which may subsequently serve as a protective layer 110. Semiconductor device structure 100 may further include additional, unlabeled layers or features.

The material from which etch stop layer 130 is formed may be compatible with the function to be performed thereby, including serving as an etch stop during the etching of containers 140. Etch stop layer 130 may be any material etchable with halogenated-carbon compounds, halogenated-sulfur compounds, or other polymer forming chemistries. For example, etch stop layer 130 may comprise a nitride (e.g., silicon nitride); an oxide (e.g., a doped or undoped silicon dioxide), an oxynitride, polysilicon, or any other suitable material. Etch stop layer 130 may be formed by any suitable process known in the art (e.g., chemical vapor deposition (CVD), pulsed CVD, atomic layer deposition (ALD), etc.), dependent at least in part, of course, upon the type of material or materials from which etch stop layer 130 is formed. Etch stop layer 130 may have any thickness compatible with the thickness of protective layer 110, an intermediate layer 120 to be etched, and the bias power used during etching. When removal of material from etch stop layer 130 is desired, if bias power is too low or etch stop layer 130 is too thick, then reactive species will be unable to etch sufficiently deep into etch stop layer 130.

Intermediate layer 120 may include an insulative material. For example, when used to form containers 140, intermediate layer 120 may include borophosphosilicate glass (BPSG) and/or phosphosilicate glass (PSG). Suitable processes for forming intermediate layer 120 include, but are not limited to, deposition processes (e.g., CVD, etc.). Of course, when used to form containers 140, the thickness of intermediate layer 120 is consistent with the desired heights of containers 140.

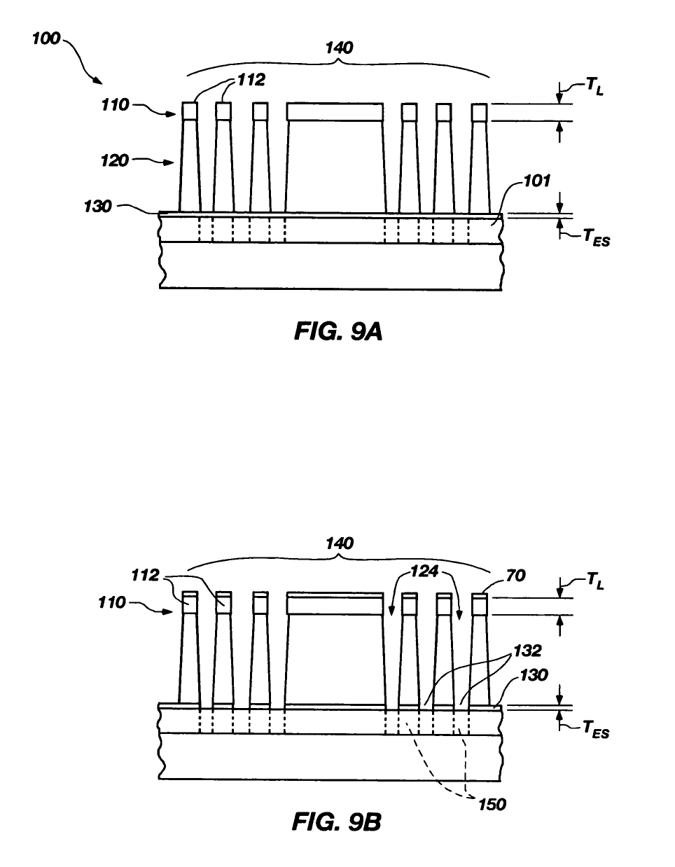

Protective layer 110 may initially have a thickness that is only thick enough or slightly thicker (e.g., about 100 Å) than necessary to provide a suitable amount of structural support to containers during further processing of semiconductor device structure 100. Prior to effecting a punch through process, protective layer 110 may have a thickness of about 600 Å to about 1,000 Å (e.g., about 800 Å), or any other thickness that may be sufficient for providing a desired level of structural support for walls 122 of containers 140, as shown in FIG. 9A. If protective layer 110 is to be employed as a hard mask, it may have an initial thickness that exceeds the thickness of a protective lattice 112 formed therefrom to accommodate any material removal that may occur as containers 140 are subsequently patterned. By way of nonlimiting example, after punch through processing, the finished thickness T_{L} of protective lattice 112 may be about 700 Å to about 800 Å, as shown in FIG. 9B, and the thickness T_{ES} of etch stop layer 130 may be about 190 Å, as shown in FIGS. 9A and 9B.

Protective layer 110 may be formed from silicon nitride or any other suitable material (e.g., a silicon oxide, a silicon oxynitride, polysilicon, etc.). Known processes (e.g., deposition processes, such as CVD, pulsed CVD, ALD, etc.), which depend at least partially upon the type of material from which protective layer 110 is formed, may be used to form protective layer 110. Of course, protective layer 110 may be thicker than is required to provide the desired amount of structural support to walls 122 of containers 140. Protective layer 110 may be any thickness that does not result in an aspect ratio so high as to prevent the complete etching of containers 140.

When used with other types of semiconductor device features, protective layer 110 may serve as a structural support, a mask, a passivation layer, a conductive layer, a barrier layer, an insulative layer, a dielectric layer, or a layer with any other functionality. Protective layer 110 may or may not be present in a completed semiconductor device.

Containers 140 may have any shape and extend through one or more material layers. A single container 140 or a plurality of identical or different containers 140 may be formed. Containers 140 may serve as substrates upon which high aspect ratio, high surface area capacitors will be fabricated. Containers 140 may be a part of or an intermediate structure in the formation of any semiconductor device component including: capacitors, transistors, diodes, trench-isolation structures, and electrical connections.

In the depicted orientation, containers 140 include substantially vertically oriented walls 122. Protective lattice 112 is located at the top edges of walls 122 of containers 140. Protective lattice 112 may be configured to protect or provide structural support to walls 122.

FIGS. 2A through 6B are scanning electron microscope (SEM) images of cross-sectional slices of semiconductor device structures 100 that incorporate teachings of embodiments of the invention. In the examples shown in FIGS. 2A through 6B, walls 122 form upstanding oval, tubular containers 140 that protrude relative to an active surface 101 of semiconductor device structure 100. Containers 140 may serve as substrates for container capacitors. For example, containers 140 may be used to form single-, double-, or multiple-sided capacitors.

In a process according to embodiments of the invention, an etch stop layer 130, an intermediate layer 120 (which may include a single layer or two or more sublayers), and a protective layer 110 may be deposited atop an active surface 101 of a semiconductor device structure 100. Protective layer 110 and intermediate layer 120 may be patterned by known processes (e.g., the formation of a mask and material removal, or etching processes) to form protective lattice 112 from protective layer 110 and containers 140 from intermediate layer 120. The resulting structure is depicted in FIG. 9A. As shown in FIG. 2, some material may also be removed from portions of etch stop layer 130 that are exposed through containers 140 as containers 140 are defined.

Turning now to FIG. 9B, material of etch stop layer 130 may then be removed (e.g., by etching) through openings 124 of containers 140. Such material removal may be effected partially or completely through etch stop layer 130. For example, openings 132 may be formed completely through etch stop layer 130 to expose features 170, such as contact plugs or active-device regions that are located beneath etch stop layer 130. The process of removing material of etch stop layer 130 (e.g., exposing features 170 beneath etch stop layer 130, which is referred to as a “punch etch”) may be effected by a dry etch process, in which bias power or a combination of bias and source power may be used to strip one or more electrons from reactant gas molecules to form a plasma of ions, free radicals, or other reactive species. The plasma removes materials (e.g., the material or materials of etch stop layer 130, as desired. The removal of material by the plasma is dependent, at least in part, upon the amount of power that is used to generate the plasma, which, in turn, affects the generation of ions, free radicals, and other reactive species, as well as ion acceleration.

In addition to the plasma removing material, a polymer 70 may be formed. Polymer 70 may form from molecules of reactive species reacting with each other, by way of etching products, or by reactions between reactive species and etching products. Polymer 70 is most likely to form where the power that is used to generate or maintain an etching plasma is relatively low. For example, a consistently low plasma-generating power may be used to continually generate polymer 70 during the process of punching through desired locations of etch stop layer 130. When the plasma-generating power is sufficiently low to generate a plasma, but sufficiently high to prevent too much polymer 70 from being formed, the resulting polymer 70 may be deposited on protective lattice 112, or protective layer 110, without being deposited into openings 124 (which may have extremely high aspect ratios of, for example, about 10:1, about 20:1, or greater) through containers 140 and, thus, onto regions of etch stop layer 130 where punch-through is desired.

By depositing polymer 70 primarily on protective lattice 112, or protective layer 110, polymer 70 protects protective lattice 112, or protective layer 110, allowing etch stop layer 130 to be etched at a faster rate than the rate at which protective lattice 112, or protective layer 110, are etched. For example, and not to limit the scope of embodiments of the invention, when etch stop layer 130 and protective lattice 112 are both composed of silicon nitride, material may be removed from etch stop layer 130 several times (e.g., six times, seven times, eight times, nine times, ten times, etc.) faster than material is removed from protective lattice 112, or protective layer 110. Consequently, during and after the punch etch of etch stop layer 130, protective lattice 112 may continue to have a thickness TL that is substantially the same as (e.g., within about 100 Å or about 200 Å of) the initial thickness TL of protective lattice 112.

The punch etch may be performed ex situ to etching of containers 140. For example, the punch etch may occur after containers 140 are etched, after an ex situ mask strip, and after a wet clean to remove any polymer remaining from an oxide etch of containers 140. The punch etch may be performed in situ with the etching of containers 140, and continue once containers 140 have been formed.

The amount of polymer 70 that is formed and deposited may be determined, at least in part, by the amount of power applied to the plasma. Polymer 70 may be formed and deposited primarily during an initial strike, in which a relatively low amount of power and, possibly, increased pressure (e.g., when the LAM 2300 DFC reactor is used) are applied to reactants to generate, or ignite, a plasma. Alternatively, the formation and deposition of polymer 70 may occur in a more consistent fashion once reactor conditions have stabilized to levels at which material removal occurs in a desired manner. The amount of power that is applied to reactant gases is tailored to provide a sufficient amount of reactive species that will remove material in the desired manner, as well as a sufficient amount of reactive species that will cause the formation and deposition of polymer 70 in the desired manner.

For example, after an initial strike, if the power is turned off, then reactive species within the plasma may polymerize. Further, if the amount of power applied to the plasma is too low, then too much polymer 70 may be formed, with little or none of it being removed, which may stall the desired punch through process. In addition, if too little power is applied to the plasma, reactive species therein that would otherwise remove material in the desired manner may not reach or effectively remove material if they reach etch stop layer 130. If, in contrast, too much power is applied to a plasma, then the plasma species may be accelerated too much, resulting in the removal of polymer 70 from protective lattice 112, or protective layer 110, at a rate that is about the same as or even exceeds the rate at which polymer 70 is deposited. Alternatively, polymer 70 may not form at all when too much power is applied to a plasma.

Pressure within a reactor may also affect the formation and usefulness of polymer 70 in processes according to embodiments of the invention. Increased pressure may result in increased polymerization of reactant gases. If the pressure is too low, polymer 70 may be sputtered from protective lattice 112, or protective layer 110, onto which it has been deposited. Additionally, walls 122 of containers 140 may be etched. For example, if the pressure within a reaction chamber is below about 45 milliTorr (mT), a LAM 2300 DFC reactor will not operate.

Additionally, the rates at which reactant gases flow into the chambers of reactors may affect the formation, deposition, and removal of polymer 70. For example, if the reactant flow rate is too low, insufficient polymer 70 may be formed to adequately hinder the removal of protective lattice 112, or protective layer 110, by the reactive species.

Other parameters that may be varied include, but are not limited to, the temperature within a chamber of a reactor, the temperatures of one or more features of a reactor, or a combination thereof.

One or more of the depths and aspect ratios of the openings 124 of containers 140, the thickness and/or composition of etch stop layer 130, and the desired affects on protective lattice 112 may affect the process parameters that will provide the desired results. In addition, parameters that are useful for effecting processes that incorporate teachings of embodiments of the invention depend, at least in part, upon the type and other characteristics of the reactor in which such processes are effected, the reactant gases, and other etch parameters.

Etchants that are suitable for use in processes that incorporate teachings of embodiments of the invention include reactant gases that generate reactive species that may remove material of etch stop layer 130 and that may form polymer. Examples of reactant gases that may be used in accordance with teachings of embodiments of the invention include, but are not limited to, carbon- and halogen-containing compounds, such as iodinated, chlorinated, and fluorinated hydrocarbons. More specific examples include, without limitation, CF₄, CHF₃, CH₂F₂, CH₃F, C₂F₂, C₂F₆, C₂HF₅, C₃F₈, C₄F₈, C₄F₆, and C₅F₈ or combinations thereof. Other examples of reactant gases that may be used include, without limitation, sulfur- and halogen-containing compounds and nitrogen- and halogen-containing compounds (e.g., sulfur hexafluoride or nitrogen trifluoride). One or more of oxygen, hydrogen, and inert noble gases may be included in a mixture of etchant gases.

Once material has been removed from etch stop layer 130 in the desired manner, further processing of semiconductor device structure 100 may be effected. For example, and not by way of limitation, any polymer 70 remaining on protective lattice 112 may be removed therefrom by known, suitable processes, such as by subjecting semiconductor device structure 110 to an ex situ oxygen plasma (i.e., in another reaction chamber). Semiconductor device structure 100 may then be cleaned by known processes, and additional features, such as the conductive and dielectric layers of capacitors, overlying conductive lines, and the like, fabricated thereon by known processes.

FIGS. 5A and 5B depict polymer 70 that has been deposited on protective lattice 112 during the punch etch. FIG. 5B depicts that polymer 70 may be deposited only on protective lattice 112 without depositing on the surfaces of walls 122 of containers 140, while FIG. 5A shows that substantially no polymer 70 has been deposited or otherwise resides in openings 132. Optionally, although not shown, polymer 70 may also deposit on the surfaces of walls 122.

### EXAMPLE 1

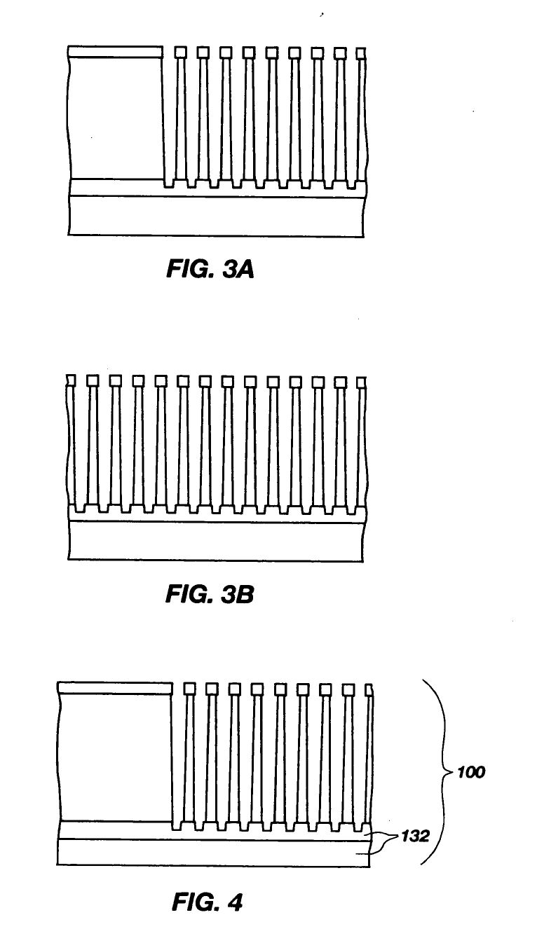

FIGS. 3A and 3B illustrate an outcome of experimentally determining parameters for using a LAM 2300 DFC reactor to remove material from an etch stop layer 130 that includes silicon nitride without substantially removing material from protective lattice 112 that also include silicon nitride. FIGS. 3A and 3B depict that an opening 132 was formed through etch stop layer 130.

During the punch etch, only a bias-power, or bottom-power, of a LAM 2300 DFC reactor was used. Following a strike phase, a pressure of 50 mT was maintained in the chamber while two separate bias powers were supplied: 200 Watts (W) @2 megaHertz (MHz) and 800 W @ 27 MHz. Both bias powers were independently controlled and run at the same time. The 2 MHz bias power controls the ion energy level. The 27 MHz bias power controls the amount of ionization. At the same time, the following reactant gases were supplied at the respectively identified flow rates: CHF₃ at 80 standard cubic centimeters per minute (sccm), CH₂F₂ at 25 sccm, C₄F₆ at 5 sccm, and HeO₂ (30% O₂) at 30 sccm. Hexafluorobutadiene (C₄F₆) was included because it may promote the formation and/or deposition of polymer 70, but it may not be necessary, especially when reactant gases are introduced into a reactor chamber at relatively high rates. Argon, an inert gas, was also supplied into the chamber at a rate of 200 sccm. These conditions were maintained for ten seconds to effect the removal of material (a partial punch through, as depicted) of etch stop layer 130.

Data showing the results of this procedure appears in Table 1. The first column Table 1 is pre-process data. The other columns include post-process data.

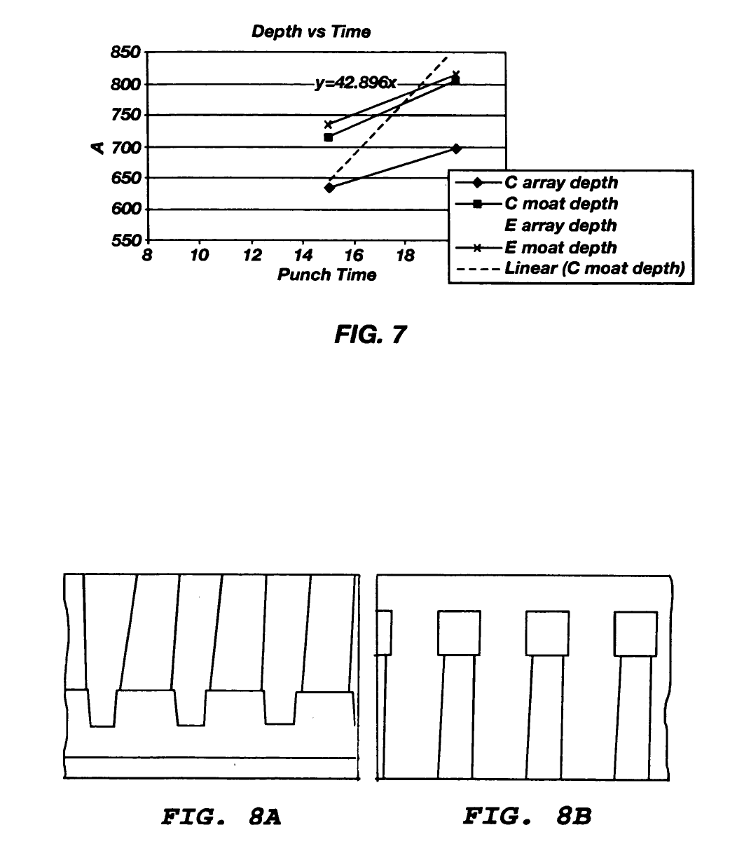

In the tables and FIG. 7, “C” refers to wafer center and “E” refers to wafer edge. “Array” refers to the portions of etch stop layer 130 that are exposed through openings 124 of containers 140. “Moat” refers to the portions of etch stop layer 130 between different containers 140. Data in each of the tables that follows is in Angstroms unless otherwise noted.

TABLE 1

| Pre-etch | C array | C moat | C lattice rib | E array | E moat | E lattice rib |
|---|---|---|---|---|---|---|
| lattice rib 112 | opening | opening | 112 | opening | opening | 112 |
| thickness | 132 depth | 132 depth | thickness | 132 depth | 132 depth | thickness |
| 1071 | 480 | 580 | 360 | 516 | 596 | 317 |

The thicknesses of protective lattice 112 were reduced by approximately 700 Å to 800 Å. Therefore, in subsequent experiments, including those set forth in EXAMPLES 2 through 4, bias power was reduced and flow rate of C₄F₆ increased.

### EXAMPLE 2

FIGS. 4, 5A, and 5B depict a semiconductor device structure 100 after a punch etch of a silicon nitride etch stop layer 130. In addition to the etch stop layer 130, protective lattice 112 of the semiconductor device structure 100 also include silicon nitride. During the punch etch, only a bias-power, or bottom-power, of a LAM 2300 DFC reactor was used.

A pressure of 50 mT was maintained in the chamber of the reactor after the strike. Also after the strike, two separate bias powers were supplied: 200 Watts (W) @ 2 megaHertz (MHz) and 500 W @ 27 MHz. Both bias powers were independently controlled and run at the same time. The 2 MHz bias power controls the ion energy level. The 27 MHz bias power controls the amount of ionization. The following reactant gases were supplied at the corresponding flow rates: CHF₃ at 80 standard cubic centimeters per minute (sccm), CH₂F₂ at 25 sccm, C₄F₆ at 8 sccm, and HeO₂ (30% O₂) at 30 sccm. Hexafluorobutadiene (C₄F₆) was included because it may promote the formation and/or deposition of polymer 70, but it may not be necessary, especially when reactant gases are introduced into a reactor chamber at relatively high rates. Argon, an inert gas, was also supplied into the chamber at a rate of 200 sccm. These conditions were maintained for ten seconds to effect partial punch through of etch stop layer 130. An initial etch rate of about 60 Å per second (Å/s) was observed. The etch rate slowed to under 20 Å/s at the end of the process.

In this example, little or no etching of protective lattice 112 was observed. Data from this example is shown below in Table 2. As with Table 1, the first column is pre-process data, while the other columns include post-process data.

TABLE 2

| Pre-etch | C array | C moat | C lattice rib | E array | E moat | E lattice rib |
|---|---|---|---|---|---|---|
| lattice rib 112 | opening 132 | opening | 112 | opening | opening | 112 |
| thickness | depth | 132 depth | thickness | 132 depth | 132 depth | thickness |
| 1071 | 634 | 714 | 1071 | 595 | 734 | 1071 |

Optimum performance at these flow rates, with these reactant gases, in this reactor, with these biases, may be possible within a range of 45 to 60 mT. However, other optimum ranges may exist by varying parameters other than pressure. This example is just one example of process parameters that may be used with a LAM 2300 DFC. Numerous variations are possible and will be apparent to one of skill in the art.

### EXAMPLE 3

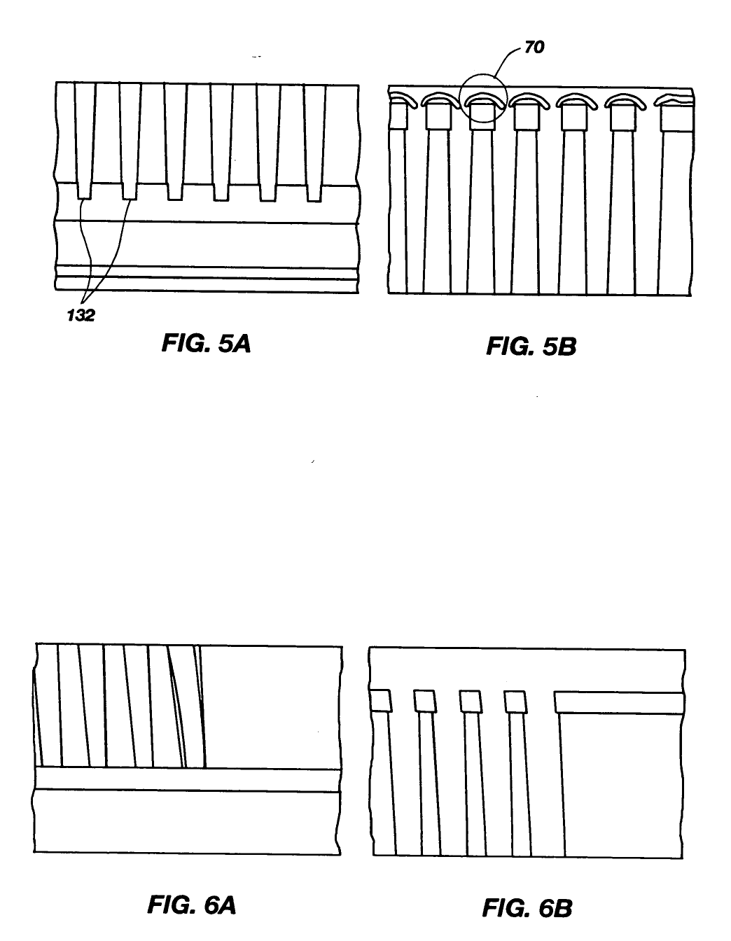

FIGS. 6A and 6B illustrate experimental results of a punch etch of an etch stop layer 130 formed from silicon nitride using a TEL DRM reactor. FIG. 6A depicts that an opening 132 was formed in etch stop layer 130. FIG. 6B depicts that approximately 100 Å was removed from protective lattice 112 that were also formed from silicon nitride.

A pressure of about 50 mT was maintained with the chamber of the reactor during the etch process. The following reactant gases were introduced into the chamber at the accompanying flow rates: CHF₃ at 80 sccm, CH₂F₂ at 25 sccm, C₄F₆ at 8 sccm, O₂ at 10 sccm, and Ar at 200 sccm. A single bias power of 750 W @13.5 MHz was used. Etching was conducted for 15 seconds. Data from this etch is shown in Table 2.

TABLE 3

| | | | | E array | E moat | | |
|---|---|---|---|---|---|---|---|
| Pre-etch | C array | C moat | C lattice | opening | opening | E lattice | Bottom |
| lattice rib 112 | opening | opening | rib 112 | 132 | 132 | rib 112 | layer 130 |
| thickness | 132 depth | 132 depth | thickness | depth | depth | thickness | etch rate |
| ~1071 | 830 | 972 | 830 | 850 | 972 | 900 | 55–65 Å/s |

These data show a small reduction in the thickness of protective lattice 112 (e.g., about 200 Å to about 300 Å). In the embodiment depicted in FIG. 6B, the tops of protective lattice 112 appear to be very rough where initial polymer formation was occurring. This may be an indication that polymer formation was not even. One contemplated solution to this situation may be to reduce the amount of oxygen supplied.

### EXAMPLE 4

Additionally, it has been demonstrated that etch rates may vary across a wafer. FIG. 7 is a graph that charts the amount of material removed from an etch stop layer 130, which includes silicon nitride, of a semiconductor device structure 100 in accordance with the process parameters of EXAMPLE 2. Etching was, however, effected for an additional five seconds (i.e., for 15 seconds total) to provide second data points for rate calculations. FIG. 7, which accounts for a preceding five second strike period, illustrates material removal rates during the additional five second period (i.e., from ten seconds into the material removal process, which appears on the x-axis of the graph at 15 seconds, to 15 seconds into the material removal process, which appears on the x-axis of the graph at 20 seconds). Cross-sectional slices of a wafer from this second etch at the increased rate are shown in FIGS. 8A and 8B. Data from this second etch is set forth in Table 4.

TABLE 4

| Pre-etch | C array | C moat | C lattice | E array | E moat | E lattice |
|---|---|---|---|---|---|---|
| lattice rib 112 | opening 132 | opening | rib 112 | opening | opening 132 | rib 112 |
| thickness | depth | 132 depth | thickness | 132 depth | depth | thickness |
| 985 | 695 | 805 | 985 | 732 | 811 | 980 |

The data charted in FIG. 7 is summarized in Table 5. The etch times in the table also account for a five second strike phase. Thus, “15” indicates that the aforementioned parameters have been maintained for ten seconds, while “20” indicates that the aforementioned parameters have been maintained for 15 seconds.

TABLE 5

| etch | C array | C moat | E array | E moat |
|---|---|---|---|---|
| time | depth | depth | depth | depth |
| 15 | 634 | 714 | 595 | 734 |
| 20 | 695 | 805 | 732 | 811 |

Thus, material may be removed from locations that are at or near the edges of a substrate at a faster rate than material may be removed from locations that are at or near the center of the substrate, or at a substantially uniform rate across all locations on the surface of the substrate.

The invention may be embodied in other specific forms without departing from its spirit or essential characteristics. The described embodiments are to be considered in all respects only as illustrative and not restrictive. The scope of the embodiments of the invention is, therefore, indicated by the appended claims rather than by the foregoing description. All changes which come within the meaning and range of equivalency of the claims are to be embraced within the scope thereof.

What is claimed:

1. A method for removing material from a semiconductor device structure, comprising:
generating a plasma;
forming polymer with reactive species of the plasma;
depositing polymer on an upper surface over a feature of the semiconductor device structure without substantially depositing polymer at locations exposed through the feature; and
removing material from the locations with reactive species of the plasma.

2. The method of claim 1, wherein generating the plasma comprises generating the plasma with at least one of a pressure, a power, and reactive gas flow rates that facilitate the acts of depositing and removing.

3. The method of claim 1, wherein generating the plasma includes generating a plasma with at least one gas that results in reactive species that facilitate formation of polymer.

4. The method of claim 3, wherein generating the plasma includes generating a plasma with gases including C₄F₆.

5. The method of claim 1, wherein depositing comprises depositing polymer on a protective structure over a container of a capacitor.

6. The method of claim 5, wherein removing comprises removing material from an etch stop layer beneath the container.

7. The method of claim 6, wherein removing comprises exposing a contact plug or an active-device region beneath the etch stop layer.

8. The method of claim 6, wherein depositing comprises depositing polymer on a protective structure comprising a same material as the etch stop layer.

9. The method of claim 8, wherein depositing comprises depositing polymer on a protective structure comprising silicon nitride.

10. The method of claim 9, wherein removing comprises removing material from an etch stop layer comprising silicon nitride.

11. The method of claim 1, wherein depositing comprises preventing material at or adjacent to the upper surface from being removed at a same rate as material is removed from the locations exposed through the feature.

12. The method of claim 11, wherein depositing comprises removing material from the locations exposed through the feature without substantially removing material at or adjacent to the upper surface.

13. The method of claim 1, wherein depositing comprises depositing polymer on an upper surface that comprises a same material as the locations exposed through the feature.

14. The method of claim 13, wherein depositing comprises depositing polymer on an upper surface comprising silicon nitride.

15. The method of claim 14, wherein removing comprises removing material from locations comprising silicon nitride that are exposed through the feature.

16. The method of claim 1, wherein removing material comprises exposing another feature located on an opposite side of the locations from the feature.

17. The method of claim 1, wherein depositing comprises depositing polymer on an element having a thickness that is substantially the same as another element of which the locations exposed through the feature are a part.

18. The method of claim 1, wherein depositing comprises depositing polymer on an element having a first thickness prior to removing material from the locations and a second thickness after removing material from the locations, a difference between the first thickness and the second thickness being less than a thickness of the material removed from the locations.

19. The method of claim 1, wherein removing material from the locations comprises removing material from the locations faster than material is removed from the upper surface of the semiconductor device structure.

20. The method of claim 1, wherein generating the plasma comprises generating the plasma from at least one of CF₄, CHF₃, CH₂F₂, CH₃F, C₂F₂, C₂F₆, C₂HF₅, C₃F₈, C₄F₈, C₄F₆, and C₅F₈.

21. The method of claim 1, wherein generating the plasma includes including sulfur, nitrogen, or halogen species in the plasma.

22. The method of claim 21, wherein generating the plasma includes including species from sulfur hexafluoride in the plasma.

23. A method for designing a semiconductor device fabrication method, comprising:
determining a desired thickness for a structure following removal of material from another structure of a semiconductor device structure;
developing a material removal protocol in which polymer will be formed and deposited onto the structure during material removal; and
configuring a fabrication process in which the structure is formed to substantially the desired thickness.

24. The method of claim 23, wherein determining comprises determining a desired thickness for a protective lattice to be located atop a container of a capacitor.

25. The method of claim 24, wherein developing the material removal protocol comprises developing a process for removing material from an etch stop layer exposed through and on an opposite side of the container from the protective lattice.

26. The method of claim 25, wherein configuring comprises configuring the fabrication process to form the protective lattice having a thickness that is substantially the same as a thickness of the etch stop layer.

27. The method of claim 26, wherein configuring comprises configuring the fabrication process to form the protective lattice to include a same material as the etch stop layer.

28. The method of claim 27, wherein configuring comprises configuring the fabrication process to form the protective lattice from silicon nitride.

29. The method of claim 26, wherein configuring comprises configuring the fabrication process to form the protective layer from a material removable by a process that will also remove a material of the etch stop layer.

30. The method of claim 23, wherein configuring comprises configuring the fabrication process to form the structure to include a same material as the another structure.

31. The method of claim 30, wherein configuring comprises configuring the fabrication process to form the structure from silicon nitride.

32. The method of claim 26, wherein configuring comprises configuring the fabrication process to form the structure from a material removable by a process that will also remove a material of the another structure.

33. The method of claim 23, wherein developing the material removal protocol comprises tailoring at least one of a chamber pressure, a reactor power, and at least one gas flow rate to provide a desired amount of polymer deposition and a desired amount of material removal.

34. The method of claim 23, wherein developing comprises developing the material removal protocol to deposit polymer onto the structure without substantially depositing polymer onto the another structure.

35. The method of claim 34, wherein developing comprises developing the material removal protocol to deposit and retain a sufficient amount of polymer on the structure to at least partially prevent removal of material from the structure while material is removed from the another structure.

36. The method of claim 23, wherein developing comprises developing a process in which a plasma is generated with reactive species from at least one of CF₄, CHF₃, CH₂F₂, CH₃F, C₂F₂, C₂F₆, C₂HF₅, C₃F₈, C₄F₈, C₄F₆, and C₅F₈.

37. The method of claim 23, wherein developing comprises developing a process in which a plasma including at least one of sulfur, nitrogen, and halogen species is generated.

38. The method of claim 37, wherein developing comprises developing a process in which a plasma including species from sulfur hexafluoride or nitrogen trifluoride are generated.

39. The method of claim 23, wherein configuring comprises configuring the fabrication process to form the structure with a thickness that exceeds a thickness of the another structure by at most about 100 Å.

40. A semiconductor device structure, comprising:
a substrate;
an etch stop layer over the substrate, with no apertures therethrough;
a capacitor container over the etch stop layer; and
a protective lattice on top edges of the capacitor container and having a thickness that is substantially the same as a thickness of the etch stop layer or thinner than a thickness of the etch stop layer.

41. The semiconductor device structure of claim 40, wherein a material of the etch stop layer and a material of the protective lattice may be removed by at least one common etchant.

42. The semiconductor device structure of claim 40, wherein the etch stop layer and the protective lattice both comprise silicon nitride.

43. A semiconductor device structure, comprising:
a substrate;
an etch stop layer over the substrate with at least one opening at least partially formed therethrough over a feature to be exposed through the etch stop layer;
a capacitor container over the etch stop layer;
a protective lattice on top edges of the capacitor container; and
a polymer coating at least an upper surface of the protective lattice, with substantially no polymer within the at least one opening of the etch stop layer.

44. The semiconductor device structure of claim 43, wherein a material of the etch stop layer and a material of the protective lattice may be removed by at least one common etchant.

45. The semiconductor device structure of claim 43, wherein the etch stop layer and the protective lattice both comprise silicon nitride.

46. The semiconductor device structure of claim 43, wherein the feature comprises an active-device region or a contact plug.
